(19) United States
(12) Patent Application Publication
(10) Pub. No.: US 2011/0159632 A1
(43) Pub. Date: Jun. 30, 2011

(54) METHOD FOR MANUFACTURING A SOLID-STATE IMAGE CAPTURING ELEMENT

(75) Inventor: Yasuhiko Sueyoshi, Osaka-shi (JP)

(73) Assignee: SHARP KABUSHIKI KAISHA, Osaka (JP)

(21) Appl. No.: 12/966,445

(22) Filed: Dec. 13, 2010

(30) Foreign Application Priority Data
Dec. 17, 2009 (JP) 2009-286990

(51) Int. Cl. H01L 31/18; H01L 31/0232

(52) U.S. Cl. 438/72; 438/75; 257/E31.11; 257/E31.128

(57) ABSTRACT

The deposition temperature of the HDP film can be controlled to 365° C. or below, preferably within a temperature range of 335° C. to 365° C., and more preferably 335° C. to 350° C., or at 350° C. Thus, it becomes possible to suppress signal deterioration due to dark current and an increase in fine white defects, and to prevent deterioration of picture quality, even when the HDP film with a favorable embedding capability between fine wiring is used as an interlayer insulation film. An RF power is set to 850 W to 1500 W, so that dark current can be suppressed even more. Further, a plasma silicon nitride film with a refractive index of 1.9 or more and 2.15 or less for a blue wavelength is formed, so that it becomes possible to suppress the lowering of a blue sensitivity in the light receiving elements to further improve picture quality.

This nonprovisional application claims priority under 35 U.S.C. §119(a) to Patent Application No. 2009-286990 filed in Japan on Dec. 17, 2009, the entire contents of which are hereby incorporated by reference.

### BACKGROUND OF THE INVENTION

1. Field of the Invention

The present invention relates to a method for manufacturing a solid-state image capturing element, which is constituted of semiconductor elements for performing a photoelectric conversion on and capturing an image of image light from a subject.

2. Description of the Related Art

Conventional solid-state image capturing elements of this type are used, for example, for an electronic information device, such as a digital camera (e.g. a digital video camera or a digital still camera), an image input camera (e.g. a monitoring camera), a scanner, a facsimile machine, a television telephone device, and a camera-equipped cell phone device. In the conventional solid-state image capturing elements, a SiN film is formed as a passivation film using a plasma CVD method, on an entire surface of the elements including a photodiode (PD), a transfer gate (TG) and a CCD; and a sintering process is performed thereon with heat. Thus, dark current on a photodiode surface can be suppressed, the photodiode functioning as a photoelectric conversion section (light receiving section) constituting each pixel. This method is disclosed in a method for manufacturing a solid-state image capturing element in Reference 1.

In Reference 1, a PSG film with a film thickness of 5000 to 6000 angstroms, for example, is formed as a first passivation film for surface protection, on an entire surface of the elements including a photodiode (PD), a transfer gate (TG) and a CCD, using a decompression CVD method, for example, with a low temperature of 400° C. On the PSG (Phospho Silicate Glasses) film, a silicon nitride film (Si₃N₄ film), i.e., a plasma SiN film, with a film thickness of 3000 to 5000 angstroms, is formed as a second passivation film, using a regular plasma CVD method with SiH₄ and ammonia (NH₃) gas, for example. Using the plasma CVD method, it is possible to resolve the constituent gases by plasma at a low temperature to form the film. If there are metal lines such as a Cu line or an Al line in an underneath layer, these metal lines will melt at a high temperature of 500° C. or more. Therefore, the film forming temperature for the plasma CVD method can be set to a low temperature of 300 to 400° C. As described above, an SiN passivation film can be formed using a plasma CVD method and a sintering process is performed thereon, so that dark current on the photodiode surface can be suppressed.

Reference 1: Japanese Laid-Open Publication No. 63-185059

### SUMMARY OF THE INVENTION

In the conventional technique described above, however, there are following problems: when an HDP film, which is favorably embedded between lines, is used as an interlayer insulation film, as wire lines become finer, depending on the film forming conditions of the HDP film, signals may deteriorate due to dark current and fine white defects may increase, thus causing deterioration of picture quality.

The present invention is intended to solve the conventional problems described above. The objective of the present invention is to provide a method for manufacturing a solid-state image capturing element, which is capable of suppressing signal deterioration due to dark current and an increase in fine white defects, and preventing deterioration of picture quality, even when an HDP film with a favorable embedding capability between fine wiring is used as an interlayer insulation film.

A method for manufacturing a solid-state image capturing element according to the present invention includes: a light receiving element forming step of forming a plurality of light receiving elements for performing a photoelectric conversion on and capturing an image of incident light, in a semiconductor substrate or a semiconductor layer; an electric charge transfer section forming step of forming each electric charge transfer section adjacent to and for each of the light receiving elements; a first HDP film forming step of forming a first HDP film, by controlling a deposition temperature at 365° C. or below, as a first interlayer insulation film, on the light receiving element and a transfer gate of the electric charge transfer section; a first contact plug forming step of forming each first contact plug in the first HDP film, the each contact plug being connected with each of a transfer gate of the electric charge transfer section and an electric charge voltage converting region, to which an electric charge is transferred; a first wiring section forming step of forming each first wiring section on the first HDP film, to be connected with the each first contact plug; a second HDP film forming step of forming a second HDP film, by controlling the deposition temperature at 365° C. or below, as a second interlayer insulation film on the first HDP film and the each first wiring section; a second contact plug forming step of forming each second contact plug in the second HDP film, the each second contact plug being connected with the each first wiring section; a second wiring section forming step of forming each second wiring section on the second HDP film, to be connected with the each second contact plug; and a first plasma silicon nitride film forming step of forming a first plasma silicon nitride film, as a passivation film, using a plasma CVD method, on the second HDP film and the each second wiring section, thereby achieving the objective described above.

A method for manufacturing a solid-state image capturing element according to the present invention includes: a light receiving element forming step of forming a plurality of light receiving elements for performing a photoelectric conversion on and capturing an image of incident light, in a semiconductor substrate or a semiconductor layer; an electric charge transfer section forming step of forming each electric charge transfer section adjacent to and for each of the light receiving elements; a first HDP film forming step of forming a first HDP film, by controlling a deposition temperature at 365° C. or below, as a first interlayer insulation film, on the light receiving element and a transfer gate of the electric charge transfer section; a first contact plug forming step of forming each first contact plug in the first HDP film, the each contact plug being connected with each of an transfer gate of the electric charge transfer section and an electric charge voltage converting region, to which an electric charge is transferred; a first wiring section forming step of forming each first wiring section on the first HDP film, to be connected with the each first contact plug; and a first plasma silicon nitride film forming step of forming a first plasma silicon nitride film, as a passivation film, using a plasma CVD method, on the first HDP film and the each first wiring section, thereby achieving the objective described above.

A method for manufacturing a solid-state image capturing element according to the present invention includes: alight receiving element forming step of forming a plurality of light receiving elements for performing a photoelectric conversion on and capturing an image of incident light, in a semiconductor substrate or a semiconductor layer; an electric charge transfer section forming step of forming each electric charge transfer section adjacent to and for each of the light receiving elements; a first HDP film forming step of forming a first HDP film, by controlling a deposition temperature at 365° C. or below, as a first interlayer insulation film, on the light receiving element and a transfer gate of the electric charge transfer section; a first contact plug forming step of forming each first contact plug in the first HDP film, the each contact plug being connected with each of an transfer gate of the electric charge transfer section and an electric charge voltage converting region, to which an electric charge is transferred; a first wiring section forming step of forming each first wiring section on the first HDP film, to be connected with the each first contact plug; a second HDP film forming step of forming a second HDP film, by controlling the deposition temperature at 365° C. or below, as a second interlayer insulation film on the first HDP film and the each first wiring section; a second contact plug forming step of forming each second contact plug in the second HDP film, the each second contact plug being connected with the each first wiring section; a second wiring section forming step of forming each second wiring section on the second HDP film, to be connected with the each second contact plug; a third HDP film forming step of forming a third HDP film, by controlling the deposition temperature at 365° C. or below, as a third interlayer insulation film on the second HDP film and the each second wiring section; a third contact plug forming step of forming each third contact plug in the third HDP film, the each third contact plug being connected with the each second wiring section; a third wiring section forming step of forming each third wiring section on the third HDP film, to be connected with the each third contact plug; and a first plasma silicon nitride film forming step of forming a first plasma silicon nitride film, as a passivation film, using a plasma CVD method, on the third HDP film and the each third wiring section, thereby achieving the objective described above.

A method for manufacturing a solid-state image capturing element according to the present invention includes: a light receiving element forming step of forming a plurality of light receiving elements for performing a photoelectric conversion on and capturing an image of incident light, in a semiconductor substrate or a semiconductor layer; an electric charge transfer section forming step of forming each electric charge transfer section adjacent to and for each of the light receiving elements; a light shielding film forming step of forming a light shielding film covering a transfer gate of the electric charge transfer section and having an aperture located above each light receiving element; a first HDP film forming step of forming a first HDP film, by controlling a deposition temperature at 365° C. or below, as a first interlayer insulation film, on the light receiving element and the light shielding film; and a first plasma silicon nitride film forming step of forming a first plasma silicon nitride film, as a passivation film, using a plasma CVD method, on the first HDP film, thereby achieving the objective described above.

Preferably, in a method for manufacturing a solid-state image capturing element according to the present invention, in the first HDP film forming step, the deposition temperature is controlled to 335° C. to 365° C., or 335° C. to 350° C., to form the first HDP film.

Still preferably, in a method for manufacturing a solid-state image capturing element according to the present invention: in the first HDP film forming step, the deposition temperature is controlled to 335° C. to 365° C., or 335° C. to 350° C., to form the first HDP film; and in the second HDP film forming step, the deposition temperature is controlled to 335° C. to 365° C., or 335° C. to 350° C., to form the second HDP film.

Still preferably, in a method for manufacturing a solid-state image capturing element according to the present invention: in the first HDP film forming step, the deposition temperature is controlled to 335° C. to 365° C., or 335° C. to 350° C., to form the first HDP film; in the second HDP film forming step, the deposition temperature is controlled to 335° C. to 365° C., or 335° C. to 350° C., to form the second HDP film; and in the third HDP film forming step, the deposition temperature is controlled to 335° C. to 365° C., or 335° C. to 350° C., to form the third HDP film.

Still preferably, in a method for manufacturing a solid-state image capturing element according to the present invention, in the first HDP film forming step, the deposition temperature is controlled to 350° C. to form the first HDP film.

Still preferably, in a method for manufacturing a solid-state image capturing element according to the present invention: in the first HDP film forming step, the deposition temperature is controlled to 350° C. to form the first HDP film; and in the second HDP film forming step, the deposition temperature is controlled to 350° C. to form the second HDP film.

Still preferably, in a method for manufacturing a solid-state image capturing element according to the present invention: in the first HDP film forming step, the deposition temperature is controlled to 350° C. to form the first HDP film; in the second HDP film forming step, the deposition temperature is controlled to 350° C. to form the second HDP film; and in the third HDP film forming step, the deposition temperature is controlled to 350° C. to form the third HDP film.

Still preferably, in a method for manufacturing a solid-state image capturing element according to the present invention: the method further includes a second plasma silicon nitride film forming step of forming a second plasma silicon nitride film, as a passivation film, using a plasma CVD method, on the light receiving element and the transfer gate of the electric charge transfer section; and in the first HDP film forming step, the first HDP film is formed on the second plasma silicon nitride film instead of the light receiving element and the transfer gate of the electric charge transfer section.

Still preferably, in a method for manufacturing a solid-state image capturing element according to the present invention: the method further includes a second plasma silicon nitride film forming step of forming a second plasma silicon nitride film, as a passivation film, using a plasma CVD method, on the light receiving element and the light shielding film; and in the first HDP film forming step, the first HDP film is formed on the second plasma silicon nitride film instead of the light receiving element and the light shielding film.

Still preferably, in a method for manufacturing a solid-state image capturing element according to the present invention, in the first plasma silicon nitride film forming step and the second plasma silicon nitride film forming step, or in the first plasma silicon nitride film forming step, a plasma silicon nitride film is formed with a refractive index of 1.9 or more and 2.15 or less for a blue wavelength, as a passivation film, using a plasma CVD method.

Still preferably, in a method for manufacturing a solid-state image capturing element according to the present invention, the method further includes a sintering process step of performing a sintering process by heating the first plasma silicon nitride film and the second plasma silicon nitride film, or the first plasma silicon nitride film.

Still preferably, in a method for manufacturing a solid-state image capturing element according to the present invention, a film thickness of the first plasma silicon nitride film and the second plasma silicon nitride film, or a film thickness of the first plasma silicon nitride film is a film thickness capable of separating an amount of hydrogen enough to supply hydrogen to a surface of the light receiving element from the plasma silicon nitride film during the sintering process.

Still preferably, in a method for manufacturing a solid-state image capturing element according to the present invention, in the first plasma silicon nitride film forming step and the second plasma silicon nitride film forming step, or in the first plasma silicon nitride film forming step, an RF power indicating a plasma generation energy and being set on a device side is set to 850 W to 1500 W to form the plasma silicon nitride film.

Still preferably, in a method for manufacturing a solid-state image capturing element according to the present invention, the second plasma silicon nitride film is formed on the light receiving element, functioning also as a reflection preventing film.

The functions of the present invention having the structures described above will be described hereinafter.

The present invention includes an HDP film forming step of forming an HDP film as an interlayer insulation film on the light receiving element and the transfer gate of the charge transfer section, by controlling a deposition temperature at or below 365° C. Further, an RF power indicating a plasma generation energy is set to 850 W to 1500 W, and a plasma silicon nitride film with a refractive index of 1.9 or more and 2.15 or less at a blue wavelength is formed.

As a result, the deposition temperature of the interlayer insulation film, or the HDP film, can be controlled to 365° C. or below, preferably within a temperature range of 335° C. to 365° C., and more preferably 335° C. to 350° C., or at 350° C. Thus, it becomes possible to suppress signal deterioration due to dark current and an increase in fine white defects, and to prevent deterioration of picture quality, even when the HDP film with a favorable embedding capability between fine wiring is used as an interlayer insulation film.

In addition, as the RF power indicating a plasma generation energy is raised to 850 W to 900 W and further to 930 W and higher, the amount of hydrogen separated from the plasma SiN film at a low temperature will increase at a later-performed sintering process, thus performing the sintering process reliably. As a result, on the surface of the light receiving elements, it becomes possible to reliably repair a defect on a silicon surface, which was caused by plasma dry etching of a metal layer, to suppress dark current even further. In addition, since the lowering of a film transmissivity of the passivation film with a blue wavelength is further suppressed, it becomes possible to suppress the lowering of a blue sensitivity in the light receiving elements to further improve picture quality.

As described above, according to the present invention, the deposition temperature of the interlayer insulation film, or the HDP film, can be controlled to 365° C. or below, preferably within a temperature range of 335° C. to 365° C., and more preferably 335° C. to 350° C., or at 350° C. Thus, it becomes possible to suppress signal deterioration due to dark current and an increase in fine white defects, and to prevent deterioration of picture quality, even when the HDP film with a favorable embedding capability between fine wiring is used as an interlayer insulation film.

In addition, an RF power indicating a plasma generation energy is set to 850 W to 1500 W, so that dark current can be suppressed even more. Further, a plasma silicon nitride film with a refractive index of 1.9 or more and 2.15 or less at a blue wavelength is formed, so that it becomes possible to suppress the lowering of a blue sensitivity in the light receiving elements to further improve picture quality.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view schematically illustrating an exemplary essential part structure of a CMOS solid-state image capturing element according to Embodiment 1 of the present invention.

FIG. 2 is a graph illustrating a relationship between a deposition temperature of HDP films and a magnitude of dark current in a CMOS solid-state image capturing element in FIG. 1.

FIG. 3 is a graph illustrating a relationship between a deposition temperature of HDP films and a variation of dark current (percentage) in a CMOS solid-state image capturing element in FIG. 1.

FIG. 4 is a graph illustrating a relationship between a deposition temperature and fine white defects, of HDP films in a CMOS solid-state image capturing element in FIG. 1.

FIG. 5 is a graph illustrating a relationship between a deposition temperature of HDP films and a variation of fine white defects (percentage) in the CMOS solid-state image capturing element in FIG. 1.

FIG. 6 is a longitudinal cross sectional view schematically illustrating an exemplary essential part structure of a CMOS solid-state image capturing element according to Embodiment 2 of the present invention.

FIG. 7 is a longitudinal cross sectional view schematically illustrating an exemplary essential part structure of a CCD solid-state image capturing element according to Embodiment 3 of the present invention.

1, 36 pixel section

2 logic transistor

10, 10A CMOS solid-state image capturing element

11, 31 semiconductor substrate

12, 32 photodiode

13 electric charge transfer section

14, 34 gate insulation film

15 transfer gate

16 HDP film (first interlayer insulation film)

17 first wiring layer

18 HDP film (second interlayer insulation film)

19 second wiring layer

20, 21 contact plug

22, 24, 41 plasma SiN film

23, 44 microlens

FD floating diffusion section

STI element dividing layer

S source (source region)

D drain (drain region)

G gate

30 CCD solid-state image capturing element

33 electric charge transfer section

35 gate electrode

37 stop layer

38 insulation film

39 light shielding film

39a aperture

40 HDP film (interlayer insulation film)

42 color filter

43 planarization film

### DESCRIPTION OF THE PREFERRED EMBODIMENTS

Hereinafter, a case will be described in detail where a plasma SiN film according to the present invention formed by using a plasma CVD method is applied to a CMOS solid-state image capturing element (CMOS image sensor), as Embodiments 1 and 2 of a method for manufacturing a solid-state image capturing element according to the present invention. Another case will be described in detail where a plasma SiN film according to the present invention formed by using a plasma CVD method is applied to a CCD solid-state image capturing element (CCD image sensor), as Embodiment 3 of a method for manufacturing a solid-state image capturing element according to the present invention.

Hereinafter, the characteristics of the CMOS image sensor and the CCD image sensor will be briefly described.

Unlike the CCD image sensor, the CMOS image sensor does not use a CCD. In the CMOS image sensor, a signal charge is transferred from each light receiving section, which performs a photoelectric conversion on incident light, in a vertical direction with a vertical transfer section, and the signal charge from the vertical transfer section is transferred in a horizontal direction with a horizontal transfer section. The CMOS image sensor reads out a signal charge from the light receiving section for each pixel with a selection control line, which is formed of an aluminum (Al) line or the like, like a memory device, and converts the signal charge into voltage. Subsequently, the CMOS image sensor successively reads out an imaging signal amplified in accordance with the converted voltage, from a selected pixel. On the other hand, the CCD image sensor requires a plurality of positive and negative power supply voltages for driving a CCD, whereas the CMOS image sensor is capable of driving itself with a single power supply, which enables a low electric consumption and low voltage driving compared with the CCD image sensor. Further, because a unique CCD manufacturing process is used for manufacturing the CCD image sensor, it is difficult to apply a manufacturing process generally used for a CMOS circuit directly to the manufacturing method for the CCD image sensor. On the other hand, the CMOS image sensor uses a manufacturing process that is generally used for a CMOS circuit. Therefore, a logic circuit, an analog circuit and an analog-digital conversion circuit and the like can be simultaneously formed by the CMOS process that is frequently used for manufacturing a driver circuit for controlling a display, a driver circuit for controlling image capturing, a semiconductor memory such as DRAM, a logic circuit and the like. That is, the CMOS image sensor is advantageous in that it is easy to form the CMOS image sensor on a same semiconductor chip on which a semiconductor memory, a driver circuit for controlling a display, and a driver circuit for controlling image capturing are formed. In addition, with respect to the manufacturing of the CMOS image sensor, the CMOS image sensor is advantageous in that it is easy for the CMOS image sensor to share a production line with the semiconductor memory, the driver circuit for controlling a display, and the driver circuit for controlling image capturing.

### Embodiment 1

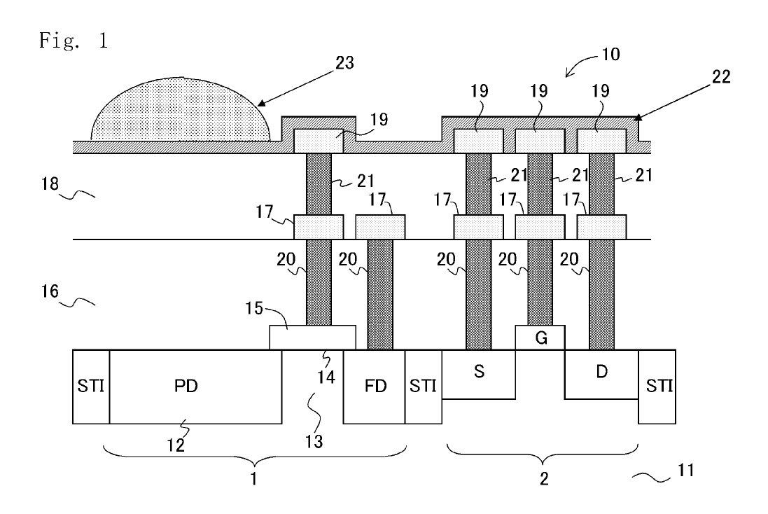

FIG. 1 is a longitudinal cross sectional view schematically illustrating an exemplary essential part structure of a CMOS solid-state image capturing element according to Embodiment 1 of the present invention.

In FIG. 1, a photodiode 12 is formed as a surface layer of a semiconductor substrate 11 in each pixel section 1 of a CMOS solid-state image capturing element 10 according to Embodiment 1. The photodiode 12 functions as a photoelectric conversion section (light receiving element) for each pixel. Adjacent to the photodiode 12, an electric charge transfer section 13 is provided in an electric charge transfer transistor for transferring a signal charge to a floating diffusion section (electric charge voltage converting section) FD. Above the electric charge transfer section 13, a transfer gate 15 is provided with a gate insulation film 14 interposed therebetween, the transfer gate 15 functioning as a lead electrode. With the electric charge transfer section 13, gate insulation film 14 and transfer gate 15, an electric charge transfer section for reading out and transferring an image signal from the photodiode 12 is constituted. Further, the pixel section includes a reading circuit, where a signal charge transferred to the floating diffusion section FD for each photodiode 12 is converted into a voltage, a signal electric potential is amplified in accordance with the converted voltage in an amplification transistor (not shown), and the reading circuit reads it out as an image signal for each pixel section.

In the reading circuit, a reset transistor for resetting the floating diffusion section FD to a predetermined voltage (e.g. power supply voltage) and an amplification transistor for amplifying an electric potential signal in accordance with an electric potential of the floating diffusion section FD after the resetting to output an image signal to a signal line, are provided in a logic transistor region 2. The logic transistor region 2 is provided between the pixel sections 1 with an element dividing layer STI interposed therebetween. The reset transistor and amplification transistor each are constituted of a source (S)/drain (D) and a gate (G).

Above the transfer gate 15, floating diffusion section FD and logic transistor region 2, a circuit wiring section of the reading circuit and a circuit wiring section connected with the transfer gate 15 and floating diffusion section FD are provided. Above the gate insulation film 14 and transfer gate 15, an HDP (High Density Plasma) film 16 (High Density Plasma film) is formed as a first interlayer insulation film with a favorable embedding capability between fine wiring. Thereabove, a first wiring layer 17 is formed. Thereabove, an HDP (High Density Plasma) film 18 (High Density Plasma film) is formed as a second interlayer insulation film with a favorable embedding capability between fine wiring. Thereabove, a second wiring layer 19 is formed. The circuit wiring section described above is thus formed.

Between the first wiring layer 17 and transfer gate 15, between the first wiring layer 17 and floating diffusion section FD, and between the first wiring layer 17 and the source (S)/drain (D) and gate (G) of the logic transistor region 2, a contact plug 20 is respectively formed, which is made of a conductive material (e.g. tungsten). Between the respective first wiring layers 17 and the respective second wiring layers 19 thereabove, a contact plug 21 is formed respectively. As a result, the wiring layers 17 and 19 made of aluminum, copper or the like, the transfer gate 15, the floating diffusion section FD, and the source (S)/drain (D) and gate (G) of the logic transistor region 2 are electrically connected with one another.

Further, above the HDP film 18 as a second interlayer insulation film and the second wiring layer 19, a plasma silicon nitride film, or a plasma SiN film 22, is formed as a passivation film. The plasma SiN film 22 is formed by using a plasma CVD method to suppress dark current (where a signal charge is produced in a state with no light) on a surface of the photodiode 12, which constitutes each pixel section 1, with a sintering process with heat, after forming a wiring pattern of the second wiring layer 19 and before forming a color filter. The plasma SiN film 22 is formed such that the refraction index of the film for a blue light (e.g. with a wavelength of 450 nm) is 2.15 or less (refractive index of 1.9 to 2.15).

Above the plasma SiN film 22, a color filter (not shown) is formed with a predetermined color arrangement of R, G and B (e.g. Bayer arrangement) arranged for each photodiode 12. Further, thereabove, a planarization film (not shown) is formed. Thereabove, a microlens 23 is formed for condensation of light to the photodiode 12 functioning as a light receiving section. In this case, the microlens 23 may be made of a color filter material. In such a case, the color filter and the planarization film will not be additionally required.

A method for manufacturing the CMOS solid-state image capturing element 10 according to Embodiment 1 with the structure described above includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a first HDP film forming step of forming an HDP film 16 by controlling a deposition temperature at 365° C. or below, as a first interlayer insulation film on the photodiode 12 and transfer gate 15; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on each HDP film 16 to be connected with each contact plug 20; a second HDP film forming step of forming an HDP film 18 by controlling a deposition temperature at 365° C. or below, as a second interlayer insulation film on the HDP film 16 and each first wiring layer 17; a second contact plug forming step of forming each second contact plug 21 connected with each first wiring layer 17, in the HDP film 18; a second wiring section forming step of forming each second wiring layer 19 to be connected with each second contact plug 21; a plasma silicon nitride film forming step of forming a plasma silicon nitride film 22 as a passivation film by using a plasma CVD method, on the HDP film 18 and each second wiring layer 19; and a sintering process step of performing a sintering process to suppress dark current on a photodiode surface by heating the plasma silicon nitride film 22.

First, with regard to the first HDP film forming step and the second HDP film forming step, a detailed description will be provided regarding forming conditions of the HDP films 16 and 18 with a favorable embedding capability between fine wiring to suppress signal deterioration due to dark current and an increase in fine white defects.

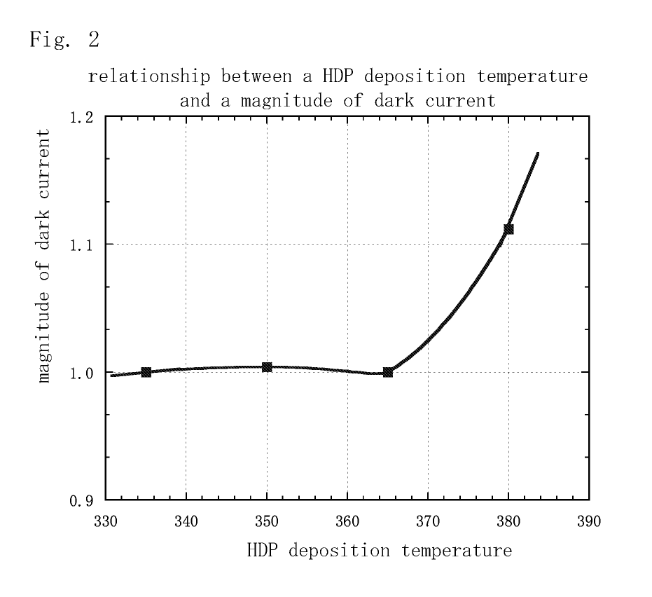

FIG. 2 is a graph illustrating a relationship between a deposition temperature of the HDP films 16 and 18 and a magnitude of dark current in the CMOS solid-state image capturing element 10 in FIG. 1.

As illustrated in FIG. 2, the magnitude of the dark current is stable at 1.0 when the deposition temperature is up to 365° C. However, when the deposition temperature (coating temperature) for the HDP films 16 and 18 exceeds 365° C., the magnitude of the dark current rapidly increases. Preferably, the deposition temperature for the HDP films 16 and 18 is from 335° C. to 365° C. in consideration of manufacture variation (since, when the temperature reaches below 335° C., an etching rate, for example, is changed, which is a hindrance to the manufacture). Therefore, the deposition temperature (coating temperature) for the HDP films 16 and 18, functioning as an interlayer insulation film, is controlled to be at 365° C. or below, and preferably from 335° C. to 365° C., so that it becomes possible to suppress signal deterioration due to dark current and to effectuate to reduce fine white defects, and to improve picture quality.

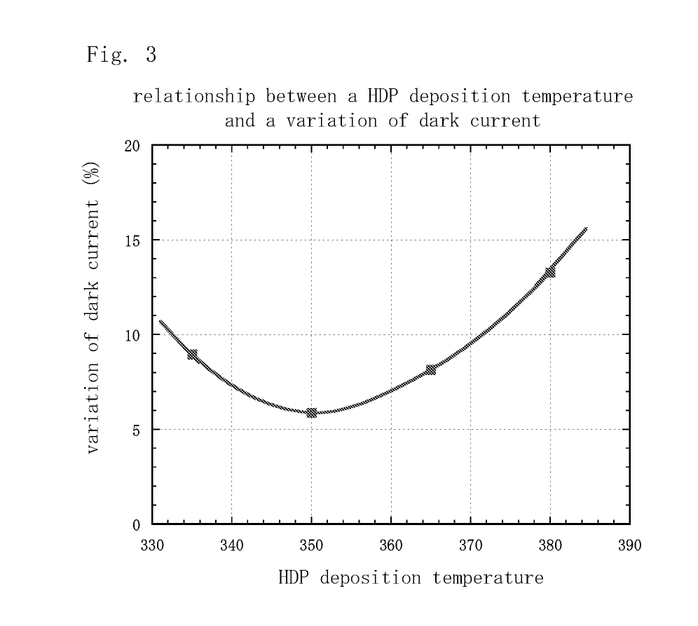

FIG. 3 is a graph illustrating a relationship between a deposition temperature and a variation of dark current (percentage), of the HDP films 16 and 18 in the CMOS solid-state image capturing element 10 in FIG. 1.

As illustrated in FIG. 3, the deposition temperature of the HDP films 16 and 18 at which the variation of dark current (percentage) becomes smallest is 350° C. Therefore, by controlling the deposition temperature of the HDP films 16 and 18 to be at 335° C. to 365° C., and most preferably at 350° C., the variation of dark current (percentage) can be suppressed and the picture quality can be improved.

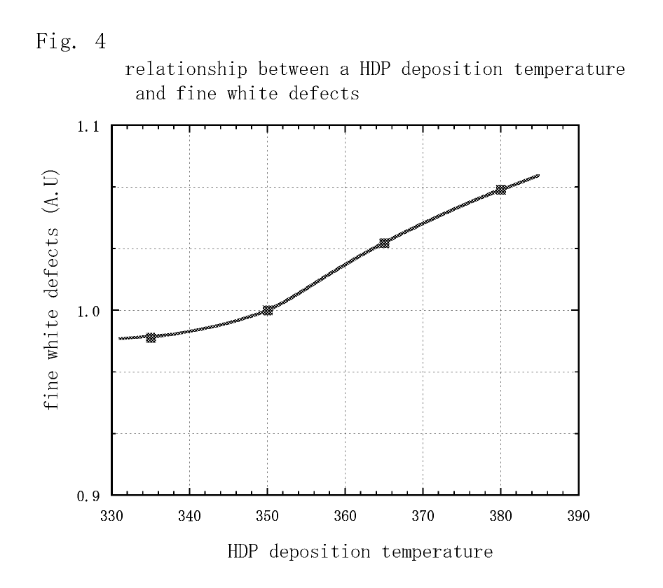

FIG. 4 is a graph illustrating a relationship between a deposition temperature and fine white defects, of the HDP films 16 and 18 in the CMOS solid-state image capturing element 10 in FIG. 1.

As illustrated in FIG. 4, the occurrence of fine white defects gently increases up to the deposition temperature of 350° C. of the HDP films 16 and 18. When the deposition temperature of the HDP films 16 and 18 exceeds 350° C., the occurrence largely increases. Even in this case, by controlling the deposition temperature (coating temperature) of the HDP films 16 and 18, functioning as an interlayer insulation film, at 365° C. or below, fine white defects can be further reduced and the picture quality can be improved. Preferably, by controlling the deposition temperature (coating temperature) of the HDP films 16 and 18, functioning as an interlayer insulation film, at 350° C. or below, fine white defects can be still further reduced and the picture quality can be further improved.

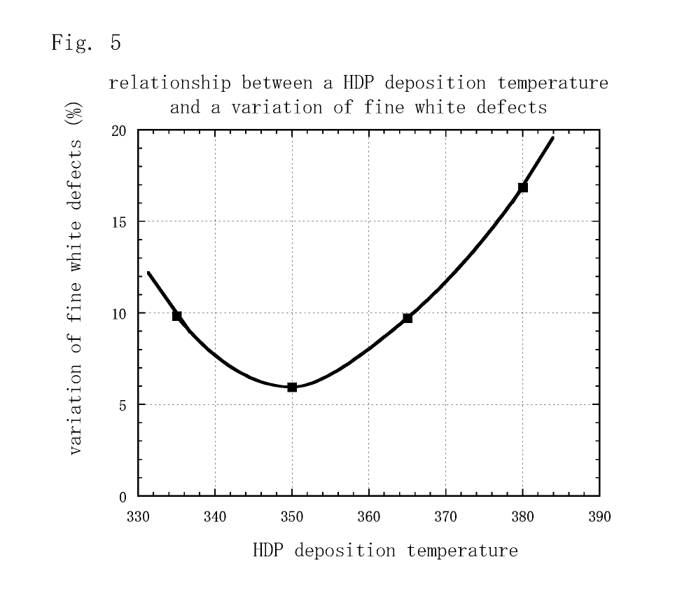

FIG. 5 is a graph illustrating a relationship between a deposition temperature and a variation of fine white defects (percentage), of the HDP films 16 and 18 in the CMOS solid-state image capturing element 10 in FIG. 1.

As illustrated in FIG. 5, the deposition temperature of the HDP films 16 and 18 at which the variation of fine white defects (percentage) becomes smallest is 350° C. Therefore, by controlling the deposition temperature of the HDP films 16 and 18 to be at 335° C. to 365° C., the variation of fine white defects (percentage) can be suppressed and the picture quality can be improved.

Next, the plasma silicon nitride film forming step will be described in detail.

The plasma SiN film 22 as a passivation film is formed such that its refractive index in a blue light (e.g. a wavelength of 450 nm) is equal to or less than 2.1 (refractive index of 1.9 to 2.1) to suppress the lowering of the film transmissivity in a blue wavelength. The film forming conditions of the plasma SiN film 22 in this case are such that the flow ratio of ammonia (NH₃) gas/SiH₄ (silane gas) is set to be 0.25 to 0.5, and the RF (Radio Frequency=high frequency) power in forming the plasma SiN film 22 is set to be in the range of 850 W or more and 1500 W or less. The flow rate of ammonia (NH₃) gas is 100 to 150 sccm, and the flow rate of SiH₄ (silane gas) is 300 to 400 sccm. The unit, sccm, means cc/per minute (a volume cc that flows for one minute).

Thus, in the plasma silicon nitride film forming step, the flow ratio of ammonia (NH₃) gas/SiH₄ (silane gas) and the RF power, which is set on the device side and indicates a plasma generation energy, are adjusted, so that the refractive index of the plasma SiN film 22 as a passivation film for a blue wavelength (e.g. a wavelength of 450 nm) can be controlled to be 1.9 to 2.15.

As a passivation film for surface protection, a silicon nitride film (Si₃N₄ film) with a film thickness of 250 nm to 350 nm (the film thickness herein is 300 nm, which is a film thickness capable of separating an amount of H₂ enough to supply hydrogen to the surface of the photodiode 12 from the SiN film during the sintering process), that is, the plasma SiN film 22, is formed using a plasma CVD method with SiH₄ (silane gas) and ammonia (NH₃) gas, with a temperature of 350° C. to 450° C. (300° C. herein) and a pressure of 2 Torr to 7 Torr (pressure of 2 Torr herein). Using the plasma CVD method, it is possible to resolve the constituent gases by plasma at a low temperature to form the plasma SiN film 22. The film forming temperature for the plasma CVD method is a low temperature of 350 to 450° C., which is favorable, if there are metal lines, such as a Cu line and an Al line, in a layer underneath the plasma SiN film 22 because these metal lines will melt at a high temperature of 500° C. or more.

As described previously, the RF (Radio Frequency=high frequency) power in forming the plasma SiN film 22 is set to be in the range of 850 W or more and 1500 W or less. More preferably, the RF power in forming the plasma SiN film 22 is set to be 930 W or more and 1130 W or less. The RF power indicates a plasma generation energy set on the device side, and is an ionizing capability for bringing constituent gases into a plasma state. The RF power means an electric power value of a high frequency for exciting a plasma.

As described above, according to Embodiment 1, the deposition temperature of the HDP films 16 and 18 is controlled to 365° C. or below, preferably within a temperature range of 335° C. to 365° C., and more preferably 335° C. to 350° C., or at 350° C. As a result, it becomes possible to suppress signal deterioration due to dark current and an increase in fine white defects, and to prevent deterioration of picture quality.

Further, as the RF power indicating a plasma generation energy is raised to 850 W to 900 W and further to 930 W and higher, the amount of hydrogen separated from the plasma SiN film 22 at a low temperature will increase at a later-performed sintering process. As a result, on the surface of the photodiode 12, it becomes possible to reliably repair a defect on a silicon surface, which was caused by plasma dry etching of a metal layer, to suppress dark current even further. In addition, since the plasma SiN film 22 with a refractive index of 1.9 or more and 2.15 or less for a blue wavelength is formed, it becomes possible to further suppress the lowering of the film transmissivity of the passivation film in a blue wavelength, thereby suppressing the lowering of a blue sensitivity in the photodiode 12 and further improving picture quality.

In Embodiment 1, as for the method for manufacturing the CMOS solid-state image capturing element 10, the case has been described where there are two wiring layers and the method includes a photodiode forming step, an electric charge transfer section forming step, a first HDP film forming step, a first contact plug forming step, a first wiring section forming step, a second HDP film forming step, a second contact plug forming step, a second wiring section forming step, a first plasma silicon nitride film forming step, and a sintering process step. However, without the limitation to this, the wiring layer may be one layer or three layers, or even a plurality of layers of four layers or more.

For example, when the wiring layer is one layer, the method for manufacturing the CMOS solid-state image capturing element includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a first HDP film forming step of forming a first HDP film 16 by controlling a deposition temperature at 365° C. or below, as a first interlayer insulation film on the photodiode 12 and transfer gate 15; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on the first HDP film 16 to be connected with each contact plug 20; a first plasma silicon nitride film forming step of forming a first plasma silicon nitride film 22 as a passivation film by using a plasma CVD method, on a first HDP film 16 and each first wiring layer 17; and a sintering process step of performing a sintering process to suppress dark current on a photodiode surface by heating the plasma silicon nitride film 22.

In addition, when the wiring layer is three layers, for example, the method for manufacturing the CMOS solid-state image capturing element includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a first HDP film forming step of forming a first HDP film 16 by controlling a deposition temperature at 365° C. or below, as a first interlayer insulation film on the photodiode 12 and transfer gate 15; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on the first HDP film 16 to be connected with each contact plug 20; a second HDP film forming step of forming a second HDP film 18 by controlling a deposition temperature at 365° C. or below, as a second interlayer insulation film on the first HDP film 16 and each first wiring layer 17; a second contact plug forming step of forming each second contact plug 21 connected with each first wiring layer 17, in the second HDP film 18; a second wiring section forming step of forming each second wiring layer 19 to be connected with each second contact plug 21; a third HDP film forming step of forming a third HDP film (not shown) by controlling a deposition temperature at 365° C. or below, as a third interlayer insulation film on the second HDP film 18 and each second wiring layer 19; a third contact plug forming step of forming each third contact plug (not shown) connected with each second wiring layer 19, in the third HDP film (not shown); a third wiring section forming step of forming each third wiring layer (not shown) to be connected with each third contact plug (not shown); a first plasma silicon nitride film forming step of forming a first plasma silicon nitride film 22 as a passivation film by using a plasma CVD method, on a third HDP film (not shown) and each third wiring layer (not shown); and a sintering process step of performing a sintering process to suppress dark current on a photodiode surface by heating the plasma silicon nitride film 22.

### Embodiment 2

Embodiment 1 described above is a case where after an aluminum (Al) wiring pattern in the upper most layer is formed and before a color filter is formed, the plasma silicon nitride film 22 is formed and a sintering process is performed. In Embodiment 2, a case will be described in detail where together with such steps, a plasma SiN film 24 to be described later is formed on a front surface side of the photodiode 12 with a gate insulation film 14, which is an oxide film, interposed therebetween, and a sintering process is performed.

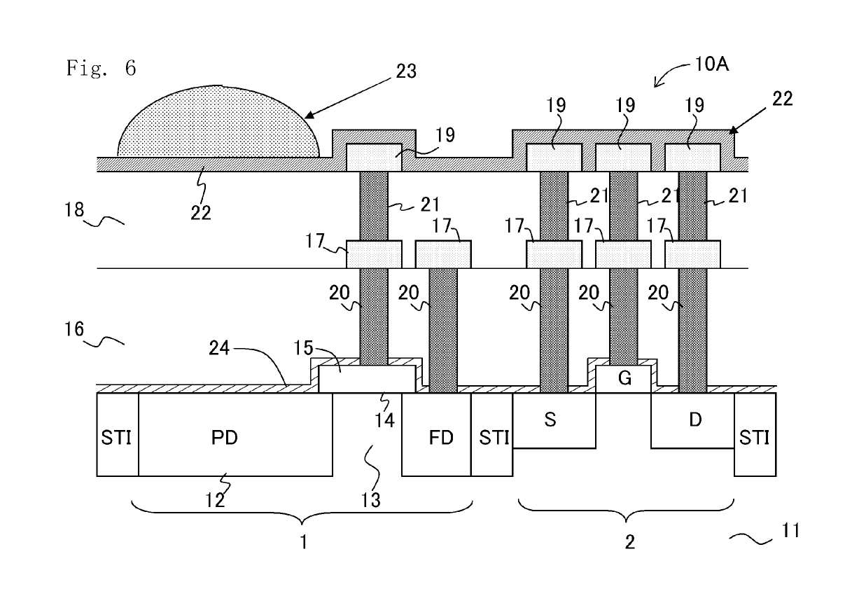

FIG. 6 is a longitudinal cross sectional view schematically illustrating an exemplary essential part structure of a CMOS solid-state image capturing element according to Embodiment 2 of the present invention. In FIG. 6, the members having the same function and effect as the corresponding ones of the CMOS solid-state image capturing element 10 in FIG. 1 are added with the same reference numerals to be described.

In FIG. 6, a photodiode 12 is formed as a surface layer of a semiconductor substrate 11 in each pixel section 1 of a CMOS solid-state image capturing element 10A according to Embodiment 2. The photodiode 12 functions as a photoelectric conversion section (light receiving element) for each pixel. Adjacent to the photodiode 12, an electric charge transfer section 13 is provided in an electric charge transfer transistor for transferring a signal charge to a floating diffusion section (electric charge voltage converting section) FD. Above the electric charge transfer section 13, a transfer gate 15 is provided with a gate insulation film 14 interposed therebetween, the transfer gate 15 functioning as a lead electrode.

On the entire surface of the gate insulation film 14 and transfer gate 15, a plasma SiN film 24 is formed as a passivation film, using a plasma CVD method, in order to suppress dark current on the surface of the photodiode 12, which constitutes each pixel section 1, with a sintering process with heat. The plasma SiN film 24 is formed such that its refractive index for a blue light (e.g. a wavelength of 450 nm) is equal to or smaller than 2.1 (a refractive index of 1.9 to 2.1).

Above the transfer gate 15, floating diffusion section FD and logic transistor region 2, formed are: a circuit wiring section of a reading circuit, where a signal charge transferred to the floating diffusion section FD for each photodiode 12 is converted into a voltage, a signal electric potential is amplified in accordance with the converted voltage and the reading circuit reads it out as an image capturing signal for each pixel section; a first wiring layer 17 on a first HDP film 16, as a first interlayer insulation film with a favorable embedding capability between fine wiring, and a second wiring layer 19 on a second HDP film 18, as a second interlayer insulation film with a favorable embedding capability between fine wiring, on top and bottom as circuit wiring sections connected to the transfer gate 15 and floating diffusion section FD.

Further, above the second HDP film 18 and the second wiring layer 19, a plasma SiN film 22 is formed as a passivation film. The plasma SiN film 22 is formed by using a plasma CVD method to suppress dark current on a surface of the photodiode 12, which constitutes each pixel section 1, with a sintering process with heat. As similar to the case with the plasma SiN film 24, the plasma SiN film 22 is formed such that its refractive index for a blue light (e.g. a wavelength of 450 nm) is equal to or smaller than 2.1 (refractive index of 1.9 to 2.1).

Above the plasma SiN film 22, a color filter (not shown) is formed with a predetermined color arrangement of R, G and B (e.g. Bayer arrangement) for each photodiode 12. Further, thereabove, a planarization film (not shown) is formed. Thereabove, a microlens 23 is formed for condensation of light to the photodiode 12 functioning as a light receiving section.

A method for manufacturing the CMOS solid-state image capturing element 10A according to Embodiment 2 with the structure described above includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a second plasma silicon nitride film forming step of forming a second plasma silicon nitride film 24 as a passivation film, using a plasma CVD method, on the photodiode 12 and transfer gate 15; a first HDP film forming step of forming a first HDP film 16 by controlling a deposition temperature at 365° C. or below, as a first interlayer insulation film on the second plasma silicon nitride film 24; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on the first HDP film 16 to be connected with each contact plug 20; a second HDP film forming step of forming a second HDP film 18 by controlling a deposition temperature at 365° C. or below, as a second interlayer insulation film on the first HDP film 16 and each first wiring layer 17; a second contact plug forming step of forming each second contact plug 21 connected with each first wiring layer 17, in the second HDP film 18; a second wiring section forming step of forming each second wiring layer 19 to be connected with each second contact plug 21; a plasma silicon nitride film forming step of forming a plasma silicon nitride film 22 as a passivation film by using a plasma CVD method, on the second HDP film 18 and each second wiring layer 19; and a sintering process step of performing a sintering process to suppress dark current on a photodiode surface by heating the plasma silicon nitride films 22 and 24.

First, with regard to the first HDP film forming step and the second HDP film forming step, forming conditions of the HDP films 16 and 18 with a favorable embedding capability between fine wiring to suppress signal deterioration due to dark current and an increase in fine white defects, are the same as the case of Embodiment 1.

That is, by controlling the deposition temperature (coating temperature) of the HDP films 16 and 18 as an interlayer insulation film to be in a temperature range of 365° C. or below, preferably from 335° C. to 365° C., and more preferably from 335° C. to 350° C., signal deterioration due to dark current can be suppressed, the reduction of fine white defects can be effectuated, and the picture quality can be improved.

In consideration of the deposition temperature of the HDP films 16 and 18 and a variation of dark current (percentage) as well as the deposition temperature of the HDP films 16 and 18 and a variation of fine white defects (percentage), the variation of dark current (percentage) and the variation of fine white defects (percentage) can be smallest when the deposition temperature of the HDP films 16 and 18 is at 350° C.

Next, passivation film forming steps (first plasma silicon nitride film forming step and second plasma silicon nitride film forming step) in the method for manufacturing the CMOS solid-state image capturing element 10A according to Embodiment 2 will be described in detail.

Each of the plasma SiN films 22 and 24 as a passivation film is formed such that its refractive index for a blue light (e.g. a wavelength of 450 nm) is 1.9 to 2.15 (or 1.9 to 2.1), as described previously, in order to suppress the lowering of a film transmissivity in a blue waveform. The film forming conditions of the plasma SiN films 22 and 24 in this case are such that the flow ratio of ammonia (NH₃) gas/SiH₄ (silane gas) is set to be 0.25 to 0.5, and the RF (Radio Frequency=high frequency) power in forming the plasma SiN films 22 and 24 is set to be in the range of 850 W or more and 1500 W or less. The flow rate of ammonia (NH₃) gas is 100 to 150 sccm, and the flow rate of SiH₄ (silane gas) is 300 to 400 sccm.

In the first plasma silicon nitride film forming step, the transfer gate 15 on the gate insulation film 14 is formed in a predetermined gate shape by plasma dry etching, and subsequently, the plasma SiN film 24 with a refractive index of 2.1 or less is formed as a passivation film, using a plasma CVD method, on the entire surface of the gate insulation film 14 and the transfer gate 15. In this case, the RF power (W; watt) indicating a plasma generation energy and being set on the device side is set to be 850 W or more and 1500 W or less in consideration of an RF power dependency of dark current in FIG. 4 at the time of passivation film forming and an RF power dependency of a blue sensitivity in FIG. 5 at the time of passivation film forming, as described previously. Preferably, the RF power is set to be 930 W or more to 1130 W, as described previously. Using a plasma CVD method with SiH₄ (silane gas) and ammonia (NH₃) gas as constituent gases, for example, a silicon nitride film (Si₃N₄ film) with a film thickness of 250 nm to 350 nm (the film thickness herein is 300 nm, which is a film thickness capable of separating an amount of H₂ enough to supply hydrogen to the surface of the photodiode 12 from the SiN film during the sintering process), that is, the plasma SiN film 24 with a refractive index of 2.1 or less, is formed, with a temperature of 350° C. to 450° C. (300° C. herein) and a pressure of 2 Torr to 7 Torr (pressure of 2 Torr herein).

Thereby, the plasma SiN film 24 can function as a reflection preventing film, which returns light reflecting on the front surface side of the gate insulation film 14 to the side closer to the photodiode 12. In addition, a sintering process can be performed on the plasma SiN film 24 under the same conditions as Embodiment 1 as a first passivation film forming step, where the plasma SiN film 24 is formed, functioning also as a reflection preventing film, with the gate insulation film 14 interposed therebetween on the side closer to the front surface of the photodiode 12.

As described above, according to Embodiment 2, the deposition temperature of the HDP films 16 and 18 is controlled to 365° C. or below, preferably within a temperature range of 335° C. to 365° C., and more preferably 335° C. to 350° C., or at 350° C. As a result, it becomes possible to suppress signal deterioration due to dark current and an increase in fine white defects, and to prevent deterioration of picture quality.

Further, as the RF power indicating a plasma generation energy is raised to 850 W to 900 W and further to 930 W and higher, the amount of hydrogen separated from the plasma SiN films 22 and 24 at a low temperature will increase at a later-performed sintering process. As a result, on the surface of the photodiode 12, it becomes possible to reliably repair a defect on a silicon surface, which was caused by plasma dry etching of a metal layer, to suppress dark current even further. In addition, since the plasma SiN films 22 and 24 with a refractive index of 1.9 or more and 2.15 or less for a blue wavelength are formed, it becomes possible to further suppress the lowering of the film transmissivity of the passivation film at a blue wavelength, thereby suppressing the lowering of a blue sensitivity in the photodiode 12 and further improving picture quality.

In Embodiment 2, as for the method for manufacturing the CMOS solid-state image capturing element 10A, the case has been described where there are two wiring layers and the method includes a photodiode forming step, an electric charge transfer section forming step, a second plasma silicon nitride film forming step, a first HDP film forming step, a first contact plug forming step, a first wiring section forming step, a second HDP film forming step, a second contact plug forming step, a second wiring section forming step, a first plasma silicon nitride film forming step, and a sintering process step. However, without the limitation to this, the wiring layer may be one layer or three layers, or even a plurality of layers of four layers or more.

For example, when the wiring layer is one layer, the method for manufacturing the CMOS solid-state image capturing element includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a second plasma silicon nitride film forming step of forming a second plasma silicon nitride film 24 as a passivation film, using a plasma CVD method, on the photodiode 12 and transfer gate 15; a first HDP film forming step of forming a first HDP film 16 by controlling a deposition temperature at 365° C. or below, as a first interlayer insulation film on the second plasma silicon nitride film 24; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on the first HDP film 16 to be connected with each contact plug 20; a first plasma silicon nitride film forming step of forming a first plasma silicon nitride film 22 as a passivation film by using a plasma CVD method, on the first HDP film 16 and each first wiring layer 17; and a sintering process step of performing a sintering process to suppress dark current on a photodiode surface by heating the first plasma silicon nitride film 22 and the second plasma silicon nitride film 24.

In addition, when the wiring layer is three layers, for example, the method for manufacturing the CMOS solid-state image capturing element includes: a photodiode forming step of forming a plurality of photodiodes 12 for performing a photoelectric conversion on and capturing an image of incident light, on a semiconductor substrate 11 (or a semiconductor layer); an electric charge transfer section forming step of forming an electric charge transfer section 13, as an electric charge transfer means, and a transfer gate 15 adjacent to one another for each photodiode 12; a second plasma silicon nitride film forming step of forming a second plasma silicon nitride film 24 as a passivation film, using a plasma CVD method, on the photodiode 12 and transfer gate 15; a first HDP film forming step of forming a f first HDP film 16 by controlling a deposition temperature at 365° C. or below, as a first interlayer insulation film on the second plasma silicon nitride film 24; a first contact plug forming step of forming each contact plug 20 in the first HDP film 16, the each contact plug 20 being connected with each transfer gate 15 and electric charge voltage converting region (floating diffusion section FD), to which an electric charge is transferred; a first wiring section forming step of forming each first wiring layer 17 on the first HDP film 16 to be connected with each contact plug 20; a second HDP film forming step of forming a second HDP film 18 by controlling a deposition temperature at 365° C. or below, as a second interlayer insulation film on the first HDP film 16 and each first wiring layer 17; a second contact plug forming step of forming each second contact plug 21 connected with each first wiring layer 17, in the second HDP film 18; a second wiring section forming step of forming each second wiring layer 19 to be connected with each second contact plug 21; a third HDP film forming step of forming a third HDP film (not shown) by controlling a deposition temperature at 365° C. or below, as a third interlayer insulation film on the second HDP film 18 and each second wiring layer 19; a third contact plug forming step of forming each third contact plug (not shown) connected with each second wiring layer 19, in the third HDP film (not shown); a third wiring section forming step of forming each third wiring layer (not shown) to be connected with each third contact plug (not shown); a first plasma silicon nitride film forming step of forming a first plasma silicon nitride film 22 as a passivation film by using a plasma CVD method, on a third HDP film (not shown) and each third wiring layer (not shown); and a sintering process step of performing a sintering process to suppress dark current on a photodiode surface by heating the plasma silicon nitride films 22 and 24.

### Embodiment 3

In Embodiments 1 and 2 described above, the case has been described where the present invention, in which the deposition temperature of the HDP films 16 and 18 is controlled at 365° C. or below, is applied to a CMOS solid-state image capturing element. In Embodiment 3, a case will be described where the present invention, in which the deposition temperature of the HDP films 16 and 18 is controlled at 365° C. or below, is applied to a CCD solid-state image capturing element.

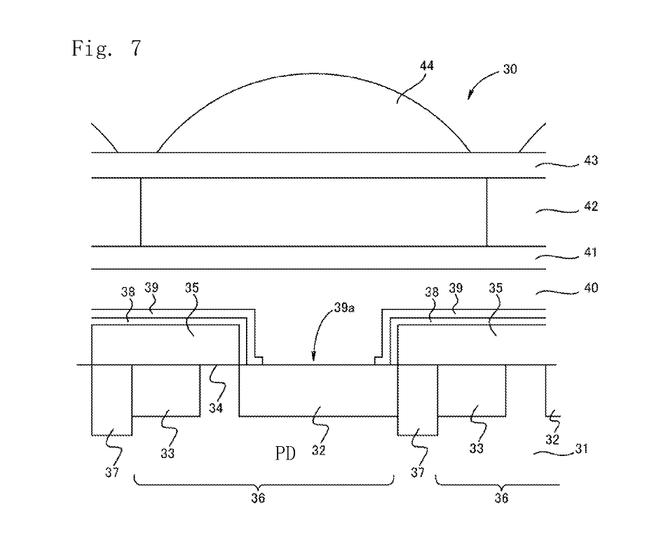

FIG. 7 is a longitudinal cross sectional view schematically illustrating an exemplary essential part structure of a CCD solid-state image capturing element according to Embodiment 3 of the present invention.

In FIG. 7, in each pixel section of a CCD solid-state image capturing element 30 according to Embodiment 3, a photodiode 32 is provided in a semiconductor substrate 31, the photodiode 32 being for performing a photoelectric conversion on incident light and generating a signal electric charge as a light receiving element. Adjacent to each photodiode 32, an electric charge transfer section 33 is disposed for transferring a signal electric charge from the photodiode 32. Thereabove, with a gate insulation film 34 interposed therebetween, a gate electrode 35 is disposed as an electric charge transfer electrode for controlling electric charge transfer of the read-out signal electric charge. A stop layer 37 is provided as an element separating layer between pixel sections 36 (in horizontal direction), the pixel section 36 consisting of the photodiode 32 and electric charge transfer section 33.

Above the gate electrode 35, a light shielding film 39 is formed, with an insulation layer 38 interposed therebetween, to prevent noise by incident light reflecting off the gate electrode 35. In addition, an aperture 39a is formed in the light shielding film 39 and above the photodiode 32.

An HDP (high density plasma) film 40 (high density plasma film) is formed as an interlayer insulation film for planarizing a level difference between the surface of the photodiode 32 and the light shielding film 39. As previously described, the HDP film 40 has a favorable embedding capability between fine wiring. Above the HDP film 40 as an interlayer insulation film, the RF power (W; watt) indicating a plasma generation energy and being set on the device side is set to be 850 W or more and 1500 W or less (preferably, 930 W or more and 1130 W or less), in consideration of an RF power dependency of dark current at the time of passivation film forming and an RF power dependency of a blue sensitivity at the time of passivation film forming, as described previously. Subsequently, using a plasma CVD method, a plasma SiN film 41 is formed as a passivation film. The refractive index of the plasma SiN film 41 for a blue light (e.g. a wavelength of 450 nm) is set to be 2.1 or less.

Above the plasma SiN film 41, a color filter 42 with a predetermined color arrangement (e.g. Bayer arrangement) of R, G and B arranged for each photodiode 32 is formed. Further, thereabove, a planarization film 43 is formed. Thereabove, a microlens 44 is formed for condensation of light to the photodiode 32 functioning as a light receiving section.

A method for manufacturing the CCD solid-state image capturing element 30 according to Embodiment 3 with the structure described above includes: a photodiode forming step of forming a plurality of photodiodes 32, as light receiving elements, for performing a photoelectric conversion on and capturing an image of incident light, on a semiconductor substrate 31 (or a semiconductor layer); an electric charge transfer section forming step of forming an electric charge transfer section 33, as an electric charge transfer means, and a gate electrode 35 adjacent to one another for each photodiode 32; a light shielding film forming step of forming a light shielding film 39, covering the gate electrode 35 and having an aperture located above the photodiode 32; a first HDP film forming step of forming a first HDP film 40 by controlling a deposition temperature at 365° C. or below, as a first interlayer insulation film on the photodiode 32 and light shielding film 39; a first plasma silicon nitride film forming step of forming a first plasma silicon nitride film 41 as a passivation film, using a plasma CVD method, on the first HDP film 40; and a sintering process step of performing a sintering process to suppress dark current on a photodiode surface by heating the plasma silicon nitride film 41.

First, with regard to the first HDP film forming step, forming conditions of the HDP film 40 with a favorable embedding capability between fine wiring to suppress signal deterioration due to dark current and an increase in fine white defects, are the same as the case of Embodiments 1 and 2.

That is, by controlling the deposition temperature (coating temperature) of the HDP film 40 as an interlayer insulation film to be in a temperature range of 365° C. or below, preferably from 335° C. to 365° C. or from 335° C. to 350° C., signal deterioration due to dark current can be suppressed, the reduction of fine white defects can be effectuated, and the picture quality can be improved.

In consideration of the deposition temperature of the HDP film 40 and a variation of dark current (percentage) as well as the deposition temperature of the HDP film 40 and a variation of fine white defects (percentage), the variation of dark current (percentage) and the variation of fine white defects (percentage) can be smallest when the deposition temperature of the HDP film 40 is at 350° C.

Next, a passivation film forming step (first plasma silicon nitride film forming step) in the method for manufacturing the CCD solid-state image capturing element 30 according to Embodiment 3 will be described in detail.

The plasma SiN film 41 as a passivation film is formed such that its refractive index for a blue light (e.g. a wavelength of 450 nm) is 2.15 or less (or 1.9 to 2.15), as described previously, in order to suppress the lowering of a film transmissivity at a blue waveform. The film forming conditions of the plasma SiN film 41 in this case are such that the flow ratio of ammonia (NH₃) gas/SiH₄ (silane gas) is set to be 0.25 to 0.5, and the RF (Radio Frequency=high frequency) power in forming the plasma SiN film 41 is set to be in the range of 850 W or more and 1500 W or less. The flow rate of ammonia (NH₃) gas is 100 to 150 sccm, and the flow rate of SiH₄ (silane gas) is 300 to 400 sccm.

As similar to the case in Embodiments 1 and 2, as a passivation film for surface protection, using a plasma CVD method with SiH₄ (silane gas) and ammonia (NH₃) gas, for example, a silicon nitride film (Si₃N₄ film) with a film thickness of 250 nm to 350 nm (the film thickness herein is 300 nm, which is a film thickness capable of separating an amount of H₂ enough to supply hydrogen to the surface of the photodiode 32 from the SiN film during the sintering process), that is, the plasma SiN film 41 with a refractive index of 2.1 or less, is formed, with a temperature of 350° C. to 450° C. (300° C. herein) and a pressure of 2 Torr to 7 Torr (pressure of 2 Torr herein).

According to the structure described above, light which has entered an image capturing region, where a plurality of pixel sections 36 are arranged in a two dimensional manner, is first condensed by the microlens 44 and the light enters the photodiode 32. Next, the light which has entered the photodiode 32 is photoelectrically converted in the photodiode 32 to be a signal electric charge. The signal electric charge is read out by the electric charge transfer section 33 to be transferred successively in a predetermined direction.

As described above, according to Embodiment 3, the deposition temperature of the HDP film 40, as an interlayer insulation film, is controlled to 365° C. or below, preferably within a temperature range of 335° C. to 365° C., and more preferably at 350° C. As a result, it becomes possible to suppress signal deterioration due to dark current and an increase in fine white defects, and to prevent deterioration of picture quality.

Further, according to Embodiment 3, as the RF power is raised to 850 W to 900 W and further to 930 W and higher, the amount of hydrogen separated from the plasma SiN film 41 (plasma SiN films 22 and 24 in Embodiments 1 and 2) at a low temperature will increase at a later-performed sintering process. As a result, on the surface of the photodiode 32 (photodiode 12 in Embodiments 1 and 2), it becomes possible to reliably repair a defect on a silicon surface, which was caused by plasma dry etching of a metal layer, to suppress dark current even further. In addition, since the plasma SiN film 41 with a refractive index of 1.9 or more and 2.15 or less for a blue wavelength is formed, it becomes possible to further suppress the lowering of the film transmissivity of the passivation film at a blue wavelength, thereby suppressing the lowering of a blue sensitivity in the light receiving section and further improving picture quality.

In Embodiment 3, as a method for manufacturing the CCD solid-state image capturing element 30, the case has been described where the method includes a photodiode forming step, an electric charge transfer section forming step, a light shielding film forming step, a first HDP film forming step, a first plasma silicon nitride film forming step and a sintering process step. Without the limitation to this, the method for manufacturing the CCD solid-state image capturing element 30 may include: a photodiode forming step of forming a plurality of photodiodes 32, as light receiving elements, for performing a photoelectric conversion on and capturing an image of incident light, on a semiconductor substrate 31 (or a semiconductor layer); an electric charge transfer section forming step of forming an electric charge transfer section 33, as an electric charge transfer means, and a gate electrode 35 adjacent to one another for each photodiode 32; a light shielding film forming step of forming a light shielding film 39, covering the gate electrode 35 and having an aperture located above the photodiode 32; a second plasma silicon nitride film forming step of forming a second plasma silicon nitride film (not shown) as a passivation film, using a plasma CVD method, on the photodiode 32 and light shielding film 39; a first HDP film forming step of forming a first HDP film 40 by controlling a deposition temperature at 365° C. or below, as a first interlayer insulation film on the second plasma silicon nitride film (not shown); a first plasma silicon nitride film forming step of forming a first plasma silicon nitride film 41 as a passivation film, using a plasma CVD method, on the first HDP film 40; and a sintering process step of performing a sintering process to suppress dark current on a photodiode surface by heating the first plasma silicon nitride film 41 and the second plasma silicon nitride film.

As described above, the present invention is exemplified by the use of its preferred Embodiments 1 to 3. However, the present invention should not be interpreted solely based on Embodiments 1 to 3 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 3 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a solid-state image capturing element, which is constituted of semiconductor elements for performing a photoelectric conversion on and capturing an image of image light from a subject, and a method for manufacturing thereof. In the present invention, the deposition temperature of the interlayer insulation film, or the HDP film, can be controlled to 365° C. or below, preferably within a temperature range of 335° C. to 365° C., and more preferably at 350° C. Thus, it becomes possible to suppress signal deterioration due to dark current and an increase in fine white defects, and to prevent deterioration of picture quality, even when the HDP film with a favorable embedding capability in fine wiring is used as an interlayer insulation film.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A method for manufacturing a solid-state image capturing element, the method comprising:
a light receiving element forming step of forming a plurality of light receiving elements for performing a photoelectric conversion on and capturing an image of incident light, in a semiconductor substrate or a semiconductor layer;
an electric charge transfer section forming step of forming each electric charge transfer section adjacent to and for each of the light receiving elements;
a first HDP film forming step of forming a first HDP film, by controlling a deposition temperature at 365° C. or below, as a first interlayer insulation film, on the light receiving element and a transfer gate of the electric charge transfer section;
a first contact plug forming step of forming each first contact plug in the first HDP film, the each contact plug being connected with each of a transfer gate of the electric charge transfer section and an electric charge voltage converting region, to which an electric charge is transferred;
a first wiring section forming step of forming each first wiring section on the first HDP film, to be connected with the each first contact plug;
a second HDP film forming step of forming a second HDP film, by controlling the deposition temperature at 365° C. or below, as a second interlayer insulation film on the first HDP film and the each first wiring section;
a second contact plug forming step of forming each second contact plug in the second HDP film, the each second contact plug being connected with the each first wiring section;
a second wiring section forming step of forming each second wiring section on the second HDP film, to be connected with the each second contact plug; and
a first plasma silicon nitride film forming step of forming a first plasma silicon nitride film, as a passivation film, using a plasma CVD method, on the second HDP film and the each second wiring section.

2. A method for manufacturing a solid-state image capturing element according to claim 1, wherein:
in the first HDP film forming step, the deposition temperature is controlled to 335° C. to 365° C., or 335° C. to 350° C., to form the first HDP film; and
in the second HDP film forming step, the deposition temperature is controlled to 335° C. to 365° C., or 335° C. to 350° C., to form the second HDP film.

3. A method for manufacturing a solid-state image capturing element according to claim 1, wherein:
in the first HDP film forming step, the deposition temperature is controlled to 350° C. to form the first HDP film; and
in the second HDP film forming step, the deposition temperature is controlled to 350° C. to form the second HDP film.

4. A method for manufacturing a solid-state image capturing element according to claim 1, wherein: the method further includes a second plasma silicon nitride film forming step of forming a second plasma silicon nitride film, as a passivation film, using a plasma CVD method, on the light receiving element and the transfer gate of the electric charge transfer section; and in the first HDP film forming step, the first HDP film is formed on the second plasma silicon nitride film instead of the light receiving element and the transfer gate of the electric charge transfer section.

5. A method for manufacturing a solid-state image capturing element according to claim 4, wherein the second plasma silicon nitride film is formed on the light receiving element, functioning also as a reflection preventing film.

6. A method for manufacturing a solid-state image capturing element according to claim 1, wherein in the first plasma silicon nitride film forming step and the second plasma silicon nitride film forming step, or in the first plasma silicon nitride film forming step, a plasma silicon nitride film is formed with a refractive index of 1.9 or more and 2.15 or less for a blue wavelength, as a passivation film, using a plasma CVD method.

7. A method for manufacturing a solid-state image capturing element according to claim 1, further including a sintering process step of performing a sintering process by heating the first plasma silicon nitride film and the second plasma silicon nitride film, or the first plasma silicon nitride film.

8. A method for manufacturing a solid-state image capturing element according to claim 7, wherein a film thickness of the first plasma silicon nitride film and the second plasma silicon nitride film, or a film thickness of the first plasma silicon nitride film is a film thickness capable of separating an amount of hydrogen enough to supply hydrogen to a surface of the light receiving element from the plasma silicon nitride film during the sintering process.

9. A method for manufacturing a solid-state image capturing element according to claim 1, wherein in the first plasma silicon nitride film forming step and the second plasma silicon nitride film forming step, or in the first plasma silicon nitride film forming step, an RF power indicating a plasma generation energy and being set on a device side is set to 850 W to 1500 W to form the plasma silicon nitride film.

10. A method for manufacturing a solid-state image capturing element, the method comprising:
a light receiving element forming step of forming a plurality of light receiving elements for performing a photoelectric conversion on and capturing an image of incident light, in a semiconductor substrate or a semiconductor layer;
an electric charge transfer section forming step of forming each electric charge transfer section adjacent to and for each of the light receiving elements;
a first HDP film forming step of forming a first HDP film, by controlling a deposition temperature at 365° C. or below, as a first interlayer insulation film, on the light receiving element and a transfer gate of the electric charge transfer section;
a first contact plug forming step of forming each first contact plug in the first HDP film, the each contact plug being connected with each of an transfer gate of the electric charge transfer section and an electric charge voltage converting region, to which an electric charge is transferred;
a first wiring section forming step of forming each first wiring section on the first HDP film, to be connected with the each first contact plug; and
a first plasma silicon nitride film forming step of forming a first plasma silicon nitride film, as a passivation film, using a plasma CVD method, on the first HDP film and the each first wiring section.

11. A method for manufacturing a solid-state image capturing element according to claim 10, wherein in the first HDP film forming step, the deposition temperature is controlled to 335° C. to 365° C., or 335° C. to 350° C., to form the first HDP film.

12. A method for manufacturing a solid-state image capturing element according to claim 10, wherein in the first HDP film forming step, the deposition temperature is controlled to 350° C. to form the first HDP film.

13. A method for manufacturing a solid-state image capturing element according to claim 10, wherein: the method further includes a second plasma silicon nitride film forming step of forming a second plasma silicon nitride film, as a passivation film, using a plasma CVD method, on the light receiving element and the transfer gate of the electric charge transfer section; and in the first HDP film forming step, the first HDP film is formed on the second plasma silicon nitride film instead of the light receiving element and the transfer gate of the electric charge transfer section.

14. A method for manufacturing a solid-state image capturing element according to claim 13, wherein the second plasma silicon nitride film is formed on the light receiving element, functioning also as a reflection preventing film.

15. A method for manufacturing a solid-state image capturing element according to claim 10, wherein in the first plasma silicon nitride film forming step and the second plasma silicon nitride film forming step, or in the first plasma silicon nitride film forming step, a plasma silicon nitride film is formed with a refractive index of 1.9 or more and 2.15 or less for a blue wavelength, as a passivation film, using a plasma CVD method.

16. A method for manufacturing a solid-state image capturing element according to claim 10, further including a sintering process step of performing a sintering process by heating the first plasma silicon nitride film and the second plasma silicon nitride film, or the first plasma silicon nitride film.

17. A method for manufacturing a solid-state image capturing element according to claim 16, wherein a film thickness of the first plasma silicon nitride film and the second plasma silicon nitride film, or a film thickness of the first plasma silicon nitride film is a film thickness capable of separating an amount of hydrogen enough to supply hydrogen to a surface of the light receiving element from the plasma silicon nitride film during the sintering process.

18. A method for manufacturing a solid-state image capturing element according to claim 10, wherein in the first plasma silicon nitride film forming step and the second plasma silicon nitride film forming step, or in the first plasma silicon nitride film forming step, an RF power indicating a plasma generation energy and being set on a device side is set to 850 W to 1500 W to form the plasma silicon nitride film.

19. A method for manufacturing a solid-state image capturing element, the method comprising:
a light receiving element forming step of forming a plurality of light receiving elements for performing a photoelectric conversion on and capturing an image of incident light, in a semiconductor substrate or a semiconductor layer;
an electric charge transfer section forming step of forming each electric charge transfer section adjacent to and for each of the light receiving elements;
a first HDP film forming step of forming a first HDP film, by controlling a deposition temperature at 365° C. or below, as a first interlayer insulation film, on the light receiving element and a transfer gate of the electric charge transfer section;
a first contact plug forming step of forming each first contact plug in the first HDP film, the each contact plug being connected with each of an transfer gate of the electric charge transfer section and an electric charge voltage converting region, to which an electric charge is transferred;
a first wiring section forming step of forming each first wiring section on the first HDP film, to be connected with the each first contact plug;
a second HDP film forming step of forming a second HDP film, by controlling the deposition temperature at 365° C. or below, as a second interlayer insulation film on the first HDP film and the each first wiring section;
a second contact plug forming step of forming each second contact plug in the second HDP film, the each second contact plug being connected with the each first wiring section;
a second wiring section forming step of forming each second wiring section on the second HDP film, to be connected with the each second contact plug;
a third HDP film forming step of forming a third HDP film, by controlling the deposition temperature at 365° C. or below, as a third interlayer insulation film on the second HDP film and the each second wiring section;
a third contact plug forming step of forming each third contact plug in the third HDP film, the each third contact plug being connected with the each second wiring section;
a third wiring section forming step of forming each third wiring section on the third HDP film, to be connected with the each third contact plug; and
a first plasma silicon nitride film forming step of forming a first plasma silicon nitride film, as a passivation film, using a plasma CVD method, on the third HDP film and the each third wiring section.

20. A method for manufacturing a solid-state image capturing element according to claim 19, wherein:
in the first HDP film forming step, the deposition temperature is controlled to 335° C. to 365° C., or 335° C. to 350° C., to form the first HDP film;
in the second HDP film forming step, the deposition temperature is controlled to 335° C. to 365° C., or 335° C. to 350° C., to form the second HDP film; and
in the third HDP film forming step, the deposition temperature is controlled to 335° C. to 365° C., or 335° C. to 350° C., to form the third HDP film.

21. A method for manufacturing a solid-state image capturing element according to claim 19, wherein:
in the first HDP film forming step, the deposition temperature is controlled to 350° C. to form the first HDP film;
in the second HDP film forming step, the deposition temperature is controlled to 350° C. to form the second HDP film; and
in the third HDP film forming step, the deposition temperature is controlled to 350° C. to form the third HDP film.

22. A method for manufacturing a solid-state image capturing element according to claim 19, wherein: the method further includes a second plasma silicon nitride film forming step of forming a second plasma silicon nitride film, as a passivation film, using a plasma CVD method, on the light receiving element and the transfer gate of the electric charge transfer section; and in the first HDP film forming step, the first HDP film is formed on the second plasma silicon nitride film instead of the light receiving element and the transfer gate of the electric charge transfer section.

23. A method for manufacturing a solid-state image capturing element according to claim 22, wherein the second plasma silicon nitride film is formed on the light receiving element, functioning also as a reflection preventing film.

24. A method for manufacturing a solid-state image capturing element according to claim 19, wherein in the first plasma silicon nitride film forming step and the second plasma silicon nitride film forming step, or in the first plasma silicon nitride film forming step, a plasma silicon nitride film is formed with a refractive index of 1.9 or more and 2.15 or less for a blue wavelength, as a passivation film, using a plasma CVD method.

25. A method for manufacturing a solid-state image capturing element according to claim 19, further including a sintering process step of performing a sintering process by heating the first plasma silicon nitride film and the second plasma silicon nitride film, or the first plasma silicon nitride film.

26. A method for manufacturing a solid-state image capturing element according to claim 25, wherein a film thickness of the first plasma silicon nitride film and the second plasma silicon nitride film, or a film thickness of the first plasma silicon nitride film is a film thickness capable of separating an amount of hydrogen enough to supply hydrogen to a surface of the light receiving element from the plasma silicon nitride film during the sintering process.

27. A method for manufacturing a solid-state image capturing element according to claim 19, wherein in the first plasma silicon nitride film forming step and the second plasma silicon nitride film forming step, or in the first plasma silicon nitride film forming step, an RF power indicating a plasma generation energy and being set on a device side is set to 850 W to 1500 W to form the plasma silicon nitride film.

28. A method for manufacturing a solid-state image capturing element, the method comprising:
a light receiving element forming step of forming a plurality of light receiving elements for performing a photoelectric conversion on and capturing an image of incident light, in a semiconductor substrate or a semiconductor layer;
an electric charge transfer section forming step of forming each electric charge transfer section adjacent to and for each of the light receiving elements;
a light shielding film forming step of forming a light shielding film covering a transfer gate of the electric charge transfer section and having an aperture located above each light receiving element;
a first HDP film forming step of forming a first HDP film, by controlling a deposition temperature at 365° C. or below, as a first interlayer insulation film, on the light receiving element and the light shielding film; and
a first plasma silicon nitride film forming step of forming a first plasma silicon nitride film, as a passivation film, using a plasma CVD method, on the first HDP film.

29. A method for manufacturing a solid-state image capturing element according to claim 28, wherein in the first HDP film forming step, the deposition temperature is controlled to 335° C. to 365° C., or 335° C. to 350° C., to form the first HDP film.

30. A method for manufacturing a solid-state image capturing element according to claim 28, wherein in the first HDP film forming step, the deposition temperature is controlled to 350° C. to form the first HDP film.

31. A method for manufacturing a solid-state image capturing element according to claim 28, wherein: the method further includes a second plasma silicon nitride film forming step of forming a second plasma silicon nitride film, as a passivation film, using a plasma CVD method, on the light receiving element and the light shielding film; and in the first HDP film forming step, the first HDP film is formed on the second plasma silicon nitride film instead of the light receiving element and the light shielding film.

32. A method for manufacturing a solid-state image capturing element according to claim 31, wherein the second plasma silicon nitride film is formed on the light receiving element, functioning also as a reflection preventing film.

33. A method for manufacturing a solid-state image capturing element according to claim 28, wherein in the first plasma silicon nitride film forming step and the second plasma silicon nitride film forming step, or in the first plasma silicon nitride film forming step, a plasma silicon nitride film is formed with a refractive index of 1.9 or more and 2.15 or less for a blue wavelength, as a passivation film, using a plasma CVD method.

34. A method for manufacturing a solid-state image capturing element according to claim 28, further including a sintering process step of performing a sintering process by heating the first plasma silicon nitride film and the second plasma silicon nitride film, or the first plasma silicon nitride film.

35. A method for manufacturing a solid-state image capturing element according to claim 34, wherein a film thickness of the first plasma silicon nitride film and the second plasma silicon nitride film, or a film thickness of the first plasma silicon nitride film is a film thickness capable of separating an amount of hydrogen enough to supply hydrogen to a surface of the light receiving element from the plasma silicon nitride film during the sintering process.

36. A method for manufacturing a solid-state image capturing element according to claim 28, wherein in the first plasma silicon nitride film forming step and the second plasma silicon nitride film forming step, or in the first plasma silicon nitride film forming step, an RF power indicating a plasma generation energy and being set on a device side is set to 850 W to 1500 W to form the plasma silicon nitride film.
